(19) United States
(12) Patent Application Publication
(10) Pub. No.: US 2016/0079448 A1
(43) Pub. Date: Mar. 17, 2016

(54) ELECTROCOATED PHOTOVOLTAIC MODULES AND METHODS OF MAKING SAME

(71) Applicant: PPG Industries Ohio, Inc., Cleveland, OH (US)

(72) Inventors: Jiping Shao, Sewickley, PA (US); James E. Poole, Gibsonia, PA (US); Irina G. Schwendeman, Wexford, PA (US)

(21) Appl. No.: 14/484,803

(22) Filed: Sep. 12, 2014

(51) Int. Cl. H01L 31/0216; H01L 31/18; H01L 31/048

(52) U.S. Cl. CPC H01L 31/02167; H01L 31/0481; H01L 31/18

(57) ABSTRACT

Photovoltaic modules are disclosed. The photovoltaic module comprises a front transparency, a front contact, a semiconductor, a back contact, an electrocoat, and a back coat. Methods of making photovoltaic modules are also disclosed.

### TECHNICAL FIELD

The present disclosure relates to photovoltaic modules and, more particularly, coatings useful for coating or encapsulating photovoltaic modules.

### BACKGROUND

Photovoltaic modules produce electricity by converting electromagnetic energy into electrical energy. Photovoltaic modules use encapsulant materials to provide durability, weather resistance, and increased service life, particularly in outdoor operating environments.

There are many types of thin film photovoltaic modules that have been developed. While various materials and configurations exist among the thin film technology, most thin film photovoltaic modules comprise the following basic elements: a transparent front layer, which may be glass, transparent polymer, or transparent coating; a transparent, conductive top layer or grid that carries away current; a thin central sandwich of semiconductors that form junctions to separate charge; a back contact that is often a metal film; an encapsulant layer; and a backsheet that protects from the environment and that can provide support to the module if needed.

A bulk photovoltaic module comprises a front transparency, such as a glass sheet or a pre-formed transparent polymer sheet (for example, a polyimide sheet); an encapsulant such as ethylene vinyl acetate (EVA); photovoltaic cells comprising wafers of photovoltaic semiconducting material such as a crystalline silicon (c-Si); and a back sheet. Bulk photovoltaic modules are typically produced in a batch or semi-batch vacuum lamination process in which the module components are preassembled into a module preassembly. The preassembly process comprises depositing the encapsulant material onto the front transparency, positioning the photovoltaic cells and electrical interconnections onto the encapsulant material, depositing additional encapsulant material onto the photovoltaic cell assembly, and depositing the back sheet onto the back side encapsulant material to complete the module preassembly. The module preassembly is placed in a specialized vacuum lamination apparatus that uses a compliant diaphragm to compress the module assembly and cure the encapsulant material under reduced pressure and elevated temperature conditions to produce the laminated photovoltaic module. The process effectively laminates the photovoltaic cells between the front transparency and a back sheet with the intermediate encapsulant material securing the sealing the photovoltaic cells. A similar lamination process is often used to produce thin-film photovoltaic modules, wherein the encapsulant material and the back sheet are laminated to a front transparency comprising deposited photovoltaic thin-film layers.

While laminated photovoltaic modules may function adequately, there may be processing and handling disadvantages. For instance, the attachment of the back sheet to the module requires a vacuum lamination process that can be very labor intensive and time consuming. In bulk modules, the photovoltaic cells may shift during the lamination process, which could generate construction defects. Laminated photovoltaic modules may also suffer premature failures from moisture ingress into the module, mainly through the edges or through the back sheet, and/or from corrosion in metallic components.

The information described in this background section is not admitted to be prior art.

### SUMMARY

In a non-limiting aspect, a method for making a photovoltaic module is provided comprising electrocoating a module including a front transparency, a front contact, a semiconductor, and a back contact, thereby depositing an electrocoat onto the back contact, and depositing a back coat onto a back side of the electrocoated module opposite the front transparency.

The present disclosure also provides a photovoltaic module comprising a front transparency, a front contact, a semiconductor, a back contact comprising a metallic conducting material, an electrocoat deposited on at least the back contact, and a back coat deposited onto a back side of the electrocoated module opposite the front transparency.

It is understood that the invention disclosed and described in this specification is not limited to the aspects summarized in this Summary.

### BRIEF DESCRIPTION OF THE DRAWINGS

Various features and characteristics of the non-limiting and non-exhaustive aspects disclosed and described in this specification may be better understood by reference to the accompanying figures, in which:

FIG. 1 is a schematic diagram illustrating a thin-film photovoltaic module comprising a protective coating system;

FIG. 2 is a schematic diagram illustrating an electro-deposition system;

FIG. 3 is a schematic diagram illustrating a method of preparing a thin-film photovoltaic module comprising a protective coating system;

FIG. 4 is a schematic diagram illustrating a bulk photovoltaic module comprising a protective coating system;

FIG. 5 is a schematic diagram illustrating a method of preparing a bulk photovoltaic module comprising a protective coating system;

FIGS. 6A-6B are photographs of thin-film photovoltaic modules used in durability testing; FIG. 6A shows a back side of a control module following 1000 hours of damp heat exposure; FIG. 6B shows a back side of the module of FIG. 6A following deposition of an electrocoat and a polyurea back coat and 1000 hours of damp heat exposure testing;

FIGS. 7A-7C are photographs of thin-film photovoltaic modules used in durability testing; FIG. 7A shows the effects of 1000 hours of testing on a back side of a control module following salt spray testing; FIG. 7B shows a front side of the control module shown in FIG. 7A following deposition of an electrocoat and a polyurea back coat and 1000 hours of salt spray testing; FIG. 7C shows a front side of the control module shown in FIG. 7A following deposition of an electrocoat and a polyamide epoxy fluoropolymer back coat and 1000 hours of salt spray testing; and

FIGS. 8A-8C are photographs of thin-film photovoltaic modules used in durability testing; FIG. 8A shows the effects of 100 cycles of thermal cycling on a back side of a control module; FIG. 8B shows a back side of the control module shown in FIG. 8A following deposition of an electrocoat and a polyurea back coat and 100 cycles of thermal cycling; FIG. 8C shows a back side of the control module shown in FIG. 8A following deposition of an electrocoat and a polyamide epoxy fluoropolymer back coat and 100 cycles of thermal cycling.

The reader will appreciate the foregoing details, as well as others, upon considering the following detailed description of various non-limiting and non-exhaustive aspects according to this specification.

### DESCRIPTION

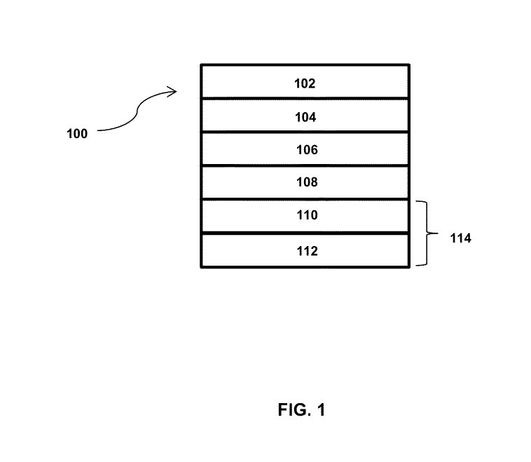

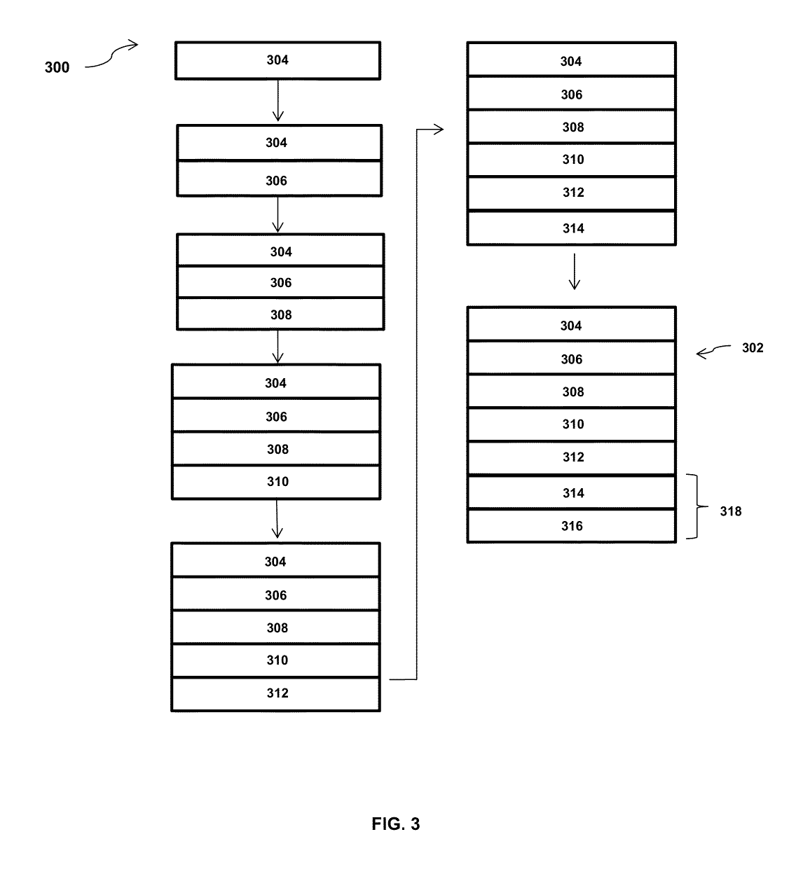

FIG. 1 illustrates an aspect of a thin-film photovoltaic module 100 comprising a front transparency 102, a front contact 104, a semiconductor 106, a back contact 108 comprising a metallic conducting material, an electrocoat 110 deposited on at least the back contact, and a back coat 112 deposited onto a back side of the electrocoated module opposite the front transparency 102. Although the photovoltaic module 100 illustrated in FIG. 1 is a thin-film photovoltaic module, in various aspects, a photovoltaic module comprises a bulk photovoltaic module (as shown in FIG. 3).

As used herein “front transparency” means a material that is transparent to electromagnetic radiation in a wavelength range that is absorbed by a photovoltaic cell to generate electricity. The front transparency comprises a planar sheet of transparent material comprising the outward-facing surface of a photovoltaic module. Suitable transparent materials that can be used for the front transparency 102 include, but are not limited to, glasses such as, for example, silicate glasses, and polymers such as, for example, polyimide, polycarbonate, and the like. Other planar sheet material that is transparent to electromagnetic radiation in a wavelength range that can be absorbed by a photovoltaic cell to generate electricity in a photovoltaic module can also be used. The term “transparent” refers to the property of a material in which at least a portion of incident electromagnetic radiation in the visible spectrum (i.e., approximately 350 to 750 nanometer wavelength) passes through the material.

It is understood that the terms “positioning,” “depositing,” and their grammatical variants, as used herein, refer to placing a referenced component in a spatial relationship with another component, wherein the components may be either placed in direct physical contact or indirectly placed beside each other with an intervening component or space. Accordingly, and by way of example, where a first component is said to be positioned or deposited on, onto, or over a second component, it is understood that the first component can be, but is not necessarily, in direct physical contact with the second component. The terms “positioning” and “depositing can be used interchangeably, but in various aspects “positioning” and its grammatical variants can refer to placing a preexisting component, such as, for example, placing a photovoltaic cell or a pre-formed sheet of material, and the term “depositing” and its grammatical variants can refer to forming a component in situ, such as, for example, applying a liquid coating layer or otherwise forming a component using a chemical or physical deposition technique.

The thin-film photovoltaic module 100 of FIG. 1 can be produced by depositing layers (or thin film laminates) onto the front transparency 102. The photovoltaic module 100 can comprise a thin-film photovoltaic module comprising a front contact 104 comprising a transparent conducting oxide layer deposited onto the front transparency 102. The transparent conducting layer or front contact 104 can be optically transparent and electrically conductive providing an optically transparent and electrically conducting junction between the front transparency 102 and the semiconductor 106. The front contact 104 can function as a window for the passage of light through to the active material semiconductor 106 and acts as an ohmic contact for the photovoltaic module 100. In one aspect, the front contact 104 comprises an inorganic material that has greater than 80% transmittance of incident light as well as electrical conductivity greater than 10³ S/cm. For example, the front contact 104 can comprise a transparent conducting oxide comprising indium tin oxide, fluorine doped tin oxide, doped zinc oxide, or combinations thereof. The front contact 104 can be deposited onto the front transparency 102 using a variety of deposition techniques. For example, the front contact 104 can be deposited using aerosol-assisted pyrolytic deposition, metal organic chemical vapor deposition (MOCVD), metal organic molecular beam deposition (MOMBD), spray pyrolysis, pulsed laser deposition (PLD), magnetron sputtering, or combinations thereof. The front contact 104 can be in direct contact with the semiconductor 106.

The semiconductor 106 can comprise a window layer deposited onto the front contact 104 and an absorber layer deposited onto the window layer. In various aspects, the semiconductor 106 comprises a window layer of photovoltaic semiconducting material (e.g., amorphous silicon, thin-film silicon, cadmium telluride, cadmium sulfide, or copper indium diselenide) deposited onto the front contact 104. For example, the window layer can comprise cadmium sulfide and the absorber layer can comprise cadmium telluride or copper indium gallium selenide. The semiconductor 106 can comprise an n-type window layer deposited onto the front contact, and a p-type absorber layer deposited onto the window layer. The semiconductor 106 can function to produce electrons available for conduction through the photovoltaic module 100.

In certain aspects of the present disclosure, the semiconductor 106 can be in contact with a metallic layer to form a back contact 108, as illustrated. The back contact 108 can comprise aluminum, nickel, molybdenum, copper, silver, gold, or combinations thereof. The back contact 108 can be deposited onto the semiconductor 106 using a variety of deposition techniques. For example, the back contact 108 can be deposited onto the semiconductor 106 using thermal spray coating, vapor deposition, chemical vapor deposition, or combinations thereof. The back contact can comprise a metallic layer deposited onto the absorber layer. The metallic layer in contact with the semiconductor 106 can function as the back contact 108 to the semiconductor 106 for conduction of electrical current through the photovoltaic module 100.

As illustrated, the photovoltaic module 100 can comprise an electrocoat 110. The electrocoat 110 can comprise a coating over at least the exposed conducting portions of the photovoltaic module 100. In certain aspects, the electrocoat 110 can comprise a cured cationic epoxy coating composition and can be deposited onto the back contact 108. For example, the electrocoat 110 can be deposited onto the back contact 108 using an electro-deposition process.

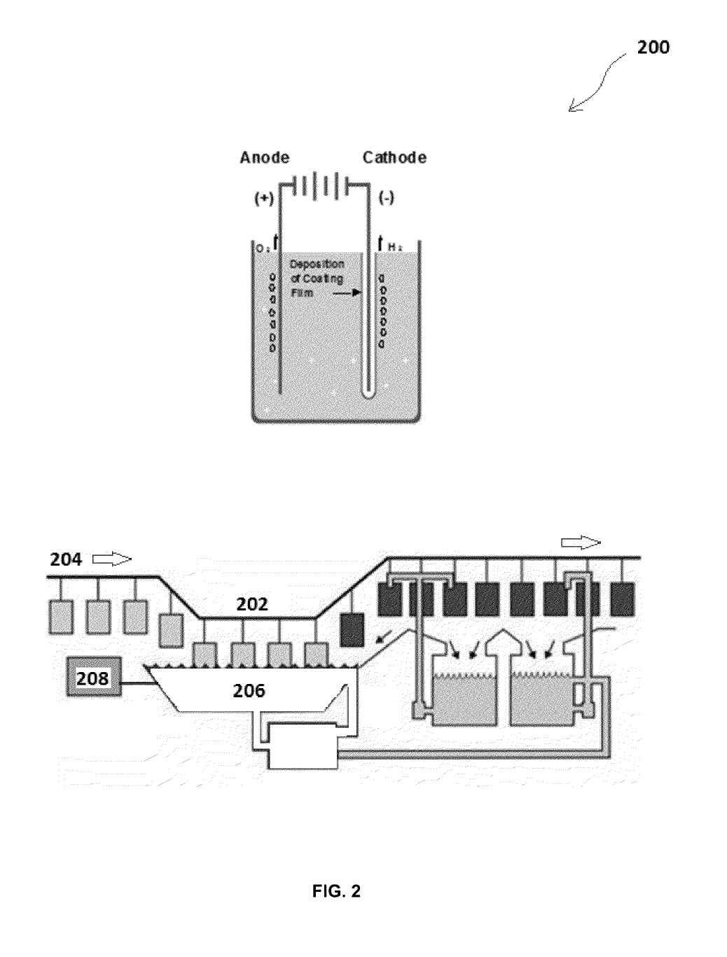

Standard electrodeposition methods and parameters can be employed in carrying out the electrocoating of the photovoltaic module. In general, the process of electrocoating can consist of an electrically conductive substrate submerged into a coating composition bath. Electricity can be applied to the part, and the charged particles can be deposited onto the substrate. As depicted in FIG. 2, an electrocoat process 200 may start after the part to be electrocoated is conveyed 202 from pretreatment 204. As shown, the part can enter into the electrocoat bath 206 where a charge may be applied from a power source 208. Current can be distributed through the part, and coating may begin to take place. In a typical process, the coating process operates on the basis of hydrolysis of water. In the cathodic system, a basic environment may be generated at the interface of the substrate. The cathodic system can cause the coating composition to precipitate onto the part forming a film of the electrocoat. As the deposition continues thickness of the film onto the surface of the part increases. Film thickness of the coating can be controlled by manipulating temperature of the bath, amount of voltage applied, or coating deposition time. Due to the nature of the electrocoating process, the deposited film may be inherently self limiting. This means that the film can eventually insulate the part so that coating may be redirected to bare areas of the part. This process is called throwpower and this is what gives electrocoating many advantages over standard spray, powder or dip applications. This property can be most advantageous when electrocoating complex shaped parts.

The electrocoating process can be used to deposit an adherent film of the electrocoat onto the photovoltaic module when a sufficient voltage can be impressed between the electrodes. The applied voltage may be varied and can be, for example, as low as one volt to as high as several thousand volts; typically the voltage can be between 50 and 400 volts. The current density can be between 1.8 ampere and 7.5 amperes per square foot and tends to decrease during electrodeposition, indicating the formation of a film. The electrocoating process can be used for electro-depositing any number of layers and any kind of layer to the photovoltaic module.

Electro-deposition coatings can comprise a water-dispersible film-forming resin. As used herein, “water-dispersible” means that a material can be soluble, dispersible, and/or emulsifiable in water. The polymers comprising the film-forming resin in electro-deposition coatings are usually ionic. For example, the film-forming resin can be cationic, a cationic acrylic, or an anionic epoxy/acrylic.

In electrocoat 110 can comprise a cationic epoxy coating composition. For example, the water-dispersible film-forming resin can comprise a cationic resin such as a cationic epoxy resin. The water-dispersible film-forming resin can be prepared, for example, by reacting together a polyepoxide and a polyhydroxyl group-containing material selected from alcoholic hydroxyl group-containing materials and phenolic hydroxyl group-containing materials. In various aspects, the water-dispersible film-forming resins suitable for use in cationic electrocoating compositions comprise, for example, cationic polymers derived from a polyepoxide, an acrylic polymer, a polyurethane, a polyester, hydroxyl group-containing polymers, amine salt group-containing polymers, or combinations thereof. Once deposited, the electrocoat 110 can be cured. The electrocoat 110 can comprise multiple deposited electrocoats over all or at least a portion of the photovoltaic module 100. The individual coats can be cured individually, as single coats, or collectively, as more than one coat, to provide a protective barrier over at least a portion of the photovoltaic module 100. In this regard, the term “cured,” as used herein, refers to the condition of a liquid coating composition in which a film or layer formed from the liquid coating composition can be at least set-to-touch. As used herein, the terms “cure” and “curing” refer to the progression of a liquid coating composition from the liquid state to a cured state and encompass physical drying of coating compositions through solvent or carrier evaporation (e.g., thermoplastic coating compositions) and/or chemical crosslinking of components in the coating compositions (e.g., thermosetting coating compositions). For example, the electrocoat can be baked in a cure oven at a suitable temperature and for a suitable time, such as, for example 375° F. (191° C.) for at least 30 minutes. In various aspects, the electrocoat can be baked in a cure oven for 10 to 30 minutes, or any sub-range subsumed therein, such as, for example, 10 to 20 minutes at a temperature in a range of 340° F. (171° C.) to 450° F. (232° C.). For example, the electrocoat can be baked in a cure oven for 15 minutes at 340° F. (171° C.).

In various aspects of the present disclosure, the electrocoat 110 provides insulation and anticorrosion properties, protecting the electrically-conducting components from environmental exposure, and/or improving the service lifetime of the thin-film photovoltaic module 100.

The electrocoat 110 can be in contact with the back coat 112. In certain aspects, the back coat 112 comprises a cured polyamide epoxy fluoropolymer coating composition, an aliphatic poly area coating composition, or combinations thereof. In various aspects, the photovoltaic module comprises a back coat comprising a coating layer formed from the coating compositions described in copending U.S. patent application entitled “Photovoltaic Modules and Methods of Making the Same” to Hensel, et al. (Attorney Docket No. 9419A1), filed concurrently herewith and which is incorporated by reference into this specification.

The back coat 112 can be deposited on at least a portion of the photovoltaic module 100, for example, onto a back side of the electrocoated module opposite the front transparency 102. Depositing the back coat 112 can comprise depositing a back coat on at least a portion of the electrocoated module. In various aspects of the present disclosure, depositing the back coat 112 comprises depositing a primer coat onto at least a portion of the electrocoated module 100 and then depositing a back coat onto the primer coat, wherein the combination of the primer coat and the back coat form the back coat 112.

Coating layers comprising the back coat 112 can be deposited onto all or a portion of the photovoltaic module 100, such as the back side of the electrocoated module opposite the front transparency 102, and cured to form a back coat or layer thereon (e.g., top coat, primer coat, tie coat, clear coat, or the like) using a suitable coating application technique. For example, the back coat can be deposited by spraying, dipping, rolling, brushing, roller coating, curtain coating, flow coating, slot die coating, and the like, and combinations thereof. The back coat 112 can be deposited directly upon a photovoltaic module or other coatings can be deposited therebetween.

The back coat 112 can comprise a dry (cured) film thickness ranging from 0.2 to 25 mils, or any sub-range subsumed therein, such as, for example, 1 to 10 mils, or 5 to 8 mils. A primer coat in between a topcoat and an electrocoated photovoltaic module can have a dry (cured) film thickness ranging from 0.2 to 10 mils, or any sub-range subsumed therein, such as, for example, 1 to 2 mils. A two- or more-layer back coat system comprising at least a topcoat and a primer coat can together have a dry (cured) film thickness ranging from 0.5 to 25 mils, or any sub-range subsumed therein, such as, for example, 1 to 10 mils, or 5 to 8 mils.

The deposited coats (including the electrocoat 110 and the backcoat 112) comprise a protective coating system 114 over all or at least a portion of the photovoltaic module 100. The individual coats can be cured individually, as single coats, or collectively, as more than one coat, to provide a protective barrier over at least a portion of the photovoltaic module 100.

The back coat 112 can function to protect the photovoltaic module 100 from abrasion, erosion, corrosion, and/or other forms of damage from environmental exposure. The back coat 112 can further provide a moisture barrier that improves the durability and extends the service life of the photovoltaic module 100.

FIG. 3 schematically illustrates one aspect of the present disclosure that provides a method 300 for making a thin-film photovoltaic module 302. The method 300 comprises depositing a transparent conducting layer onto a front transparency 304 to form a front contact 306, depositing a first semiconductor layer 308 onto the front contact 306, depositing a second semiconductor layer 310 onto the first semiconductor layer 308, depositing a metallic layer onto the second semiconductor layer 310 to form the back contact 312, depositing an electrocoat layer 314 onto the back contact 312, and depositing a back coat 316 onto a back side of the electrocoated module opposite the front transparency 304. Component layers of the photovoltaic module 302 can comprise the same or similar materials and perform the same or similar functions as those corresponding elements described above in connection with the thin-film photovoltaic module 100 shown in FIG. 1. For example, the front transparency 304, the front contact 306, the back contact 312, the electrocoat 314, and the back coat 316 can comprise the same materials and perform that same functions, respectively, as the front transparency 102, the front contact 104, the back contact 108, the electrocoat 110, and the back coat 112 of the photovoltaic module 100 of FIG. 1. The semiconductor 106 (FIG. 1) can comprise more than one semiconductor layer. For example, the semiconductor 106 can include a first semiconductor layer and a second semiconductor layer. The first and second semiconductor layers can independently comprise amorphous silicon, thin-film silicon, cadmium telluride, cadmium sulfide, copper indium gallium selenide, or combinations thereof. Referring to FIG. 3, the first semiconductor layer 308 can comprise an n-type window layer, and the second semiconductor layer 310 can comprises a p-type absorber layer.

The method 300 can comprise depositing a metallic layer onto the second semiconductor layer 310 to form the back contact 312. Similar to the back contact 108 of the photovoltaic module 100 (FIG. 1), the back contact 312 can comprise aluminum, nickel, molybdenum, copper, silver, gold, or combinations thereof.

In various aspects of the present disclosure, the method 300 can further comprise depositing an electrocoat 314 onto a surface of the back contact 312. The electrocoat 314 can comprise a cationic epoxy coating composition and can be deposited using an electro-deposition operation, as described above. The method 300 comprises depositing the back coat 316 onto a back side of the electrocoated module opposite the front transparency 304.

The method 300 can further comprise curing the electrocoat 314 deposited onto the back contact 310 before depositing the back coat 316 onto the back side of the electrocoated module, and then curing the back coat 316 deposited onto the back side of the electrocoated module. The back coat 316 can be deposited before curing the electrocoat 314 and the electrocoat 314 and the back coat 316 can be simultaneously cured. In various aspects, the method 300 comprises deposited coats (including the electrocoat 314 and the backcoat 316) comprising a protective coating system 318 over all or at least a portion of the photovoltaic module 302.

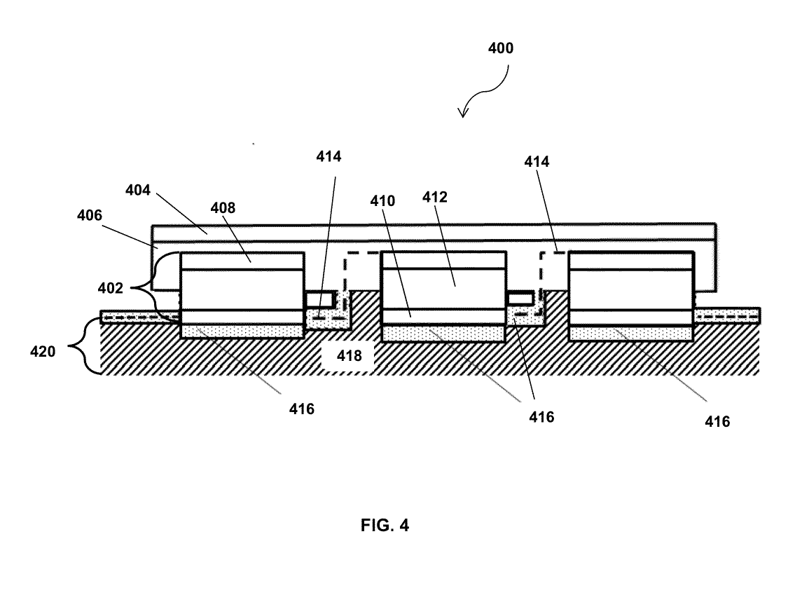

As schematically illustrated in FIG. 4, a photovoltaic module can comprise a bulk photovoltaic module 400 comprising a plurality of electrically interconnected photovoltaic cells 402 adhered to a front transparency 404 with an encapsulant material 406. The photovoltaic cells 402 can each comprise a front contact 408 and a back contact 410 on opposite sides of a semiconductor wafer 412. The photovoltaic cells 402 can be positioned with the front contact 408 facing the encapsulant material 406. In various aspects, the photovoltaic module 400 further comprises electrical interconnections 414 that link or connect the cells deposited onto the encapsulant material 406. An electrocoat 416 and a back coat 418 can be deposited on at least a portion of the back side of the photovoltaic module 400 opposite the front transparency 404. The front transparency 404 can comprise a planar sheet of transparent material comprising the outward-facing surface of the photovoltaic module 400. The front transparency 404 can comprise the same or similar materials as described above in connection with the front transparency 102 of the photovoltaic module 100. For example, a suitable transparent material can be used for the front transparency 404, including, but not limited to, glasses such as, for example, silicate glasses, and polymers such as, for example, polyimide, polycarbonate, and the like.

The encapsulant material 406 can be deposited on at least a portion of the front transparency 404. As used herein “encapsulant material” refers to polymeric materials used to adhere photovoltaic cells to front transparencies in photovoltaic modules. The encapsulant material 406 can comprise a cured clear fluid encapsulant or ethylene vinyl acetate (EVA). In various aspects, encapsulant material 406 can be formed from a solid sheet of encapsulant material such as ethylene vinyl acetate. In other aspects, the encapsulant material 406 can comprise a clear layer of cured fluid encapsulant deposited and cured onto one side of the front transparency 404. As used herein, the term “clear” refers to samples exhibiting a transmittance exceeding 85% as evaluated under ASTM E 308-06 “Standard Practice for Computing the Colors of Objects by Using the Commission Internationale de l'Eclairage (CIE) System.” For example, in various aspects the term “clear” refers to samples of 8-10 mils thickness film deposited on Solarphire PV glass (3.2 mm glass) exhibiting a transmittance exceeding 85% evaluated using the ASTM E 308-06 standard (employing an X-Rite® Color i® 7 Spectrophotometer, commercially available from X-Rite, Inc., Grand Rapids, Mich., USA) using a CIE system Y value for D65 (incandescent) illumination and a 10° standard observer. As used herein to describe a fluid encapsulant the term “fluid” includes liquids, powders and/or other materials that are able to flow into or fill the shape of a space. In various aspects, a fluid encapsulant material 406 can comprise inorganic particles, such as, for example, mica, which can be dispersed in a cured coat.

The photovoltaic cells 402 and the electrical interconnections 414 can be positioned on the encapsulant material 406 so that each photovoltaic cell 402 can be electrically connected to other cells. The photovoltaic cells 402 can comprise a semiconductor wafer 412 positioned in between two electrically conducting layers: the front contact 408 and the back contact 410. In various aspects, the semiconductor wafer 412 can be a crystalline silicon wafer. The front contact 408 can comprise a transparent conducting oxide layer or a patterned metallic layer deposited onto one side of the crystalline silicon wafer. In certain aspects, the back contact 410 comprises a metallic layer deposited onto an opposite side of the crystalline silicon wafer. The photovoltaic cells 402 can comprise ITO- and aluminum-coated crystalline silicon wafers. An assembly comprising the photovoltaic cells 402 and the electrical interconnections 414 can be positioned onto the encapsulant material 406.

The photovoltaic module 400 can comprise an electrocoat 416 and a back coat 418. The electrocoat 416 can be deposited onto at least the back contact 410 of the photovoltaic cell 402 and the electrical interconnections 414. The back coat 418 can be deposited onto a back side of the electrocoated module opposite the front transparency 404. The electrocoat 416 and the back coat 418 comprise the electrocoat and back coat materials described above in connection with FIGS. 1 and 3.

In various aspects, the back coat 418 can comprise a single coating composition deposited onto the back side of the electrocoated module opposite the front transparency 404 and can cover all or at least a portion of the photovoltaic cells 402, electrical interconnections 414, and areas of exposed encapsulant material 406. The back coat 418 can comprise the outermost backing layer of a photovoltaic module. The photovoltaic module can comprise a back coat as the outermost backing layer of the photovoltaic module, thus eliminating laminated back sheet construction. In various aspects, the back coat 418 can comprises coating layers, wherein any two or more coating layers can individually comprise the same or different coating compositions. For example, the back coat 410 can comprise a two-layer primer-topcoat system. The back coat 418 can comprise a polyamide epoxy fluoropolymer coating composition, an aliphatic polyurea coating composition, or combinations thereof.

In various aspects, a photovoltaic module of the present disclosure comprises a back coat comprising a coating layer formed from the coating compositions described in U.S. patent application “Photovoltaic Modules and Methods of Making the Same” to Hensel, et al, (Attorney Docket No. 9419A1).

The back coat 418 of the photovoltaic module 400 can comprise a primer-topcoat system. For example, the back coat 418 can comprise a two-layer coating system comprising a primer coat deposited onto the back side of the electrocoated module and a topcoat deposited onto the primer coat. The primer coat can comprise any suitable coating compositions such as, for example, DOW CORNING® 1200 OS Primer (a primer for silicone adhesives/sealants) commercially available from Dow Corning, Midland, Mich., USA. In various aspects, the primer coat comprises a thermoset polyepoxide-polyamine composition.

The back coat 418 and the electrocoat 416 may comprise a protective coating system 420. The protective coating system 420 can comprise two or more coating layers, wherein any coating layers may individually comprise the same or a different coating composition. The coating compositions used to produce the two or more coating layers (e.g., back coat, electrocoat, primer coat, topcoat, tie coat, and the like) comprising a protective coating system for a photovoltaic module can comprise inorganic particles in the coating composition and the resultant cured coating film. For example, particulate mineral materials, such as, for example, mica, may be added to coating compositions used to produce a protective coating system for photovoltaic modules. The inorganic particles can comprise aluminum, silica, clays, pigments, and/or glass flake, or any combination thereof. Inorganic particles can be added to a back coat, primer coat, and/or tie coat deposited onto the back side of a photovoltaic module. As used herein, “tie coat” refers to an intermediate coating layer intended to facilitate or enhance adhesion between an underlying coating (such as a primer or an electrocoat) and an overlying back coat.

Protective coating systems comprising inorganic particles in the cured coats may exhibit improved barrier properties such as, for example, lower moisture vapor transmission rates and/or lower permeance values. Inorganic particles such as, for example, mica and other mineral particulates, can improve the moisture barrier properties of polymeric films and coats by increasing the tortuosity of transport paths for water molecules contacting the films or coats. These improvements can be attributed to the relatively flat platelet-like structure of various inorganic particles. In various aspects, inorganic particles can comprise a platelet shape. The inorganic particles can comprise a platelet shape and have an aspect ratio, defined as the ratio of the average width dimension of the particles to the average thickness dimension of the particles, ranging from 5 to 100 microns. In various aspects, inorganic particles comprise an average particle size ranging from 10 to 40 microns.

Inorganic particles, such as, for example, mica, can be dispersed in a cured coating layer. The inorganic particles can be mechanically stirred and/or mixed into the coatings before deposition and curing. In various aspects, inorganic particles can be mixed until fully distributed without settling.

The back coat 418 may comprise a maximum water vapor permeance value ranging from 0.1 to 1,000 g*mil/m²*day, or any sub-range subsumed therein, such as, for example, 1 to 500 g*mil/m²*day. In various aspects that comprise a back coat 418 comprising a primer-topcoat system, the water vapor permeance for the primer can be less than that of the topcoat. A two- or more-layer protective coating system comprising at least a topcoat and a primer coat can together comprise a maximum permeance value ranging from 0.1 to 1,000 g*mil/m²*day, or any sub-range subsumed therein, such as, for example, 1 to 500 g*mil/m⁴ day.

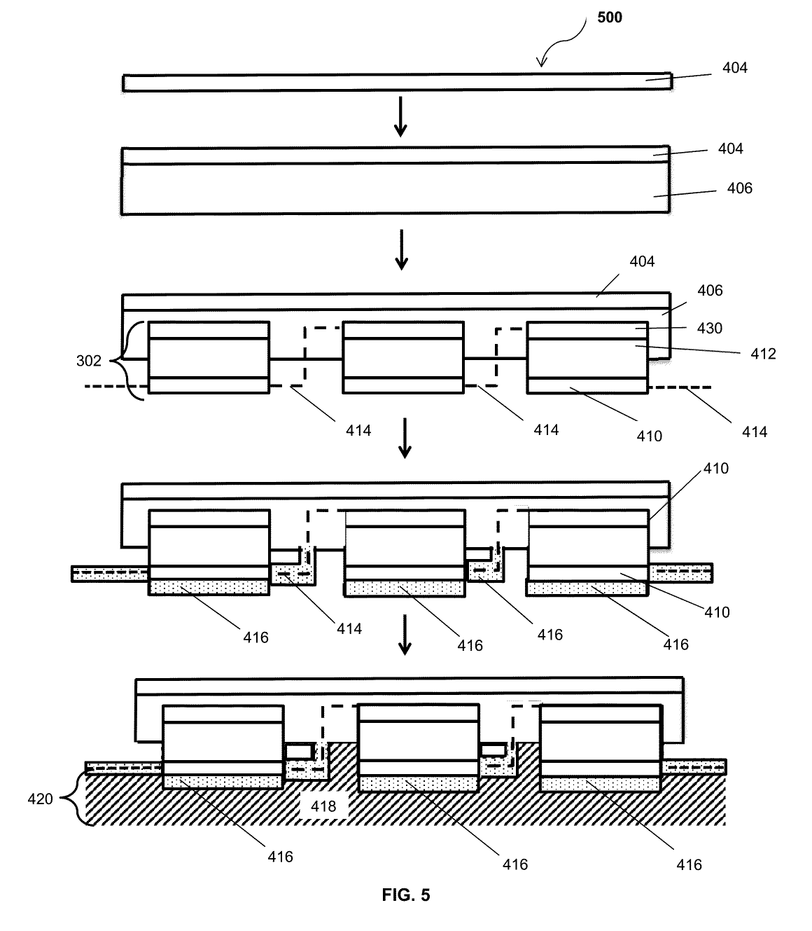

FIG. 5 illustrates a method 500 for making the photovoltaic module 400 shown in FIG. 4. In various aspects, the method 500 can comprise depositing the encapsulant material 406 onto the front transparency 404 and positioning a plurality of electrically interconnected photovoltaic cells 402 onto the encapsulant layer, the photovoltaic cells 402 each comprising a front contact 408 and a back contact 410 on opposite sides of a semiconductor 412. The semiconductor 412 can comprise a crystalline silicon wafer and the front contact 408 can comprise a transparent conducting oxide layer or a patterned metallic layer deposited onto one side of the crystalline silicon wafer, and the back contact 410 can comprise a metallic layer deposited onto an opposite side of the crystalline silicon wafer. The photovoltaic cells 402 can be positioned with the front contact 408 facing the encapsulant material 406. In certain aspects, the module comprising the front transparency 404, the encapsulant 406, and the electrically interconnected photovoltaic cells 402 can be electrocoated, thereby depositing an electrocoat 416 onto the back contact 410 and any exposed electrical interconnections 414. A back coat 418 can be deposited onto a back side of the electrocoated module opposite the front transparency 404.

Deposition of the encapsulant material 406 onto the front transparency 404 can comprise positioning a solid sheet of encapsulant material, such as, for example, EVA, onto one side of the front transparency 404. In various aspects, application of encapsulant material 406 onto the front transparency 404 can comprise depositing a clear fluid encapsulant onto one side of the front transparency 404. In various aspects, a photovoltaic module can comprise a clear fluid encapsulant comprising a coating layer formed from the coating compositions described in U.S. Patent Application Publication No. 2013/0240019 A1, which is incorporated by reference into this specification.

The photovoltaic cells 402 and the electrical interconnections 414 can be deposited or positioned onto the encapsulant material 406 in any suitable configuration. In various aspects, positioning of the photovoltaic cells 402 and the electrical interconnections 414 comprises positioning bulk photovoltaic cells and electrical interconnections on the previously-deposited encapsulant material and pressing the positioned bulk photovoltaic cells and electrical interconnections into the encapsulant material. Positioning can also include electrically connecting the cells and/or an assembly of cells. In various aspects, the encapsulant material 406 can be laminated or cured to secure the bulk photovoltaic cells 402 and the electrical interconnections 414 in place and adhere them to the front transparency 404. In various aspects, the encapsulant material 406 comprises ethylene vinyl acetate and the method 500 can further comprise laminating the encapsulant and the photovoltaic cells 402 before electrocoating the module. In various aspects, the encapsulant material 406 comprises a clear fluid encapsulant and the method 500 can further comprise curing the clear fluid encapsulant material 406 after positioning the photovoltaic cells 402 and before electrocoating the module. The electrocoat 416 can be deposited on at least a portion of the back contact 410 of the photovoltaic cells 402 and the electrical interconnections 414. In various aspects wherein the encapsulant material comprises a clear fluid encapsulant deposited onto one side of a front transparency, the fluid encapsulant can be deposited using a coating application technique such as, for example, spraying, electrostatic spraying, dipping, rolling, brushing, roller coating, curtain coating, flow coating, slot die coating, and the like, or combinations thereof.

Following the electrocoating process, the back coat 418 can be deposited onto the back side of the electrocoated module opposite the front transparency 404. In various aspects, depositing the back coat 418 comprises depositing a single back coat 418 or a two-or-more-layer coating system comprising, for example, a primer coat, a tie coat, and a back coat. The coating layers comprising the back coat 418 can be deposited onto all or a portion of the back side of the electrocoated photovoltaic module and cured using a coating application technique such as, for example, spraying, electrostatic spraying, dipping, rolling, brushing, roller coating, curtain coating, flow coating, slot die coating, and the like, or combinations thereof. The deposited coating layers can be cured individually, as single coating layers, or collectively, as two or more coating layers. In certain aspects, the cured coating system comprises a protective barrier over the back side of the photovoltaic module.

Depositing the back coat 418 can encapsulate and/or coat at least a portion of the electrocoated photovoltaic cells and electrical interconnections, thereby producing the photovoltaic module 400, as illustrated. The back coat can comprise coating layers deposited onto the back side of the electrocoated module. The back coat 418 can be cured to solidify the back coat 418 and adhere the back coat 418 to the underlying components and electrocoat material, thereby producing a protective backing layer to the photovoltaic module. In various aspects comprising a two-or-more-layer back coat system, the two or more coatings comprising the back coat 418 can be cured sequentially or can be deposited wet-on-wet and cured simultaneously.

The back coat 418 can comprise a dry (cured) film thickness ranging from 0.2 to 25 mils, or any sub-range subsumed therein, for example, 1 to 10 mils, or 5 to 8 mils. A primer coat in between a topcoat and an electrocoated photovoltaic module may include a dry (cured) film thickness ranging from 0.2 to 10 mils, or any sub-range subsumed therein, such as, for example, 1 to 2 mils. A two-or-more-layer back coat system comprising at least a topcoat and a primer coat can together have a dry (cured) film thickness ranging from 0.5 to 25 mils, or any sub-range subsumed therein, such as, for example, 1 to 10 mils, or 5 to 8 mils.

Accordingly, the present disclosure provides various aspects of methods of making a photovoltaic module. For example, in a first aspect, Aspect 1, the present disclosure provides a method for making a photovoltaic module comprising: electrocoating a module comprising a front transparency, a front contact, a semiconductor, and a back contact, thereby depositing an electrocoat onto the back contact; and depositing a back coat onto a back side of the electrocoated module opposite the front transparency.

In another aspect, Aspect 2, the present disclosure provides a method of making a photovoltaic module as provided in Aspect 1, further comprising curing the electrocoat deposited onto the back contact before depositing the back coat onto the back side of the electrocoated module; and curing the back coat deposited onto the back side of the electrocoated module.

In another aspect, Aspect 3, the present disclosure provides a method of making a photovoltaic module as provided in either Aspect 1 or Aspect 2, wherein the electrocoat comprises a cationic epoxy coating composition.

In another aspect, Aspect 4, the present disclosure provides a method of making a photovoltaic module as provided in any of Aspects 1-3, wherein the back coat comprises a polyamide epoxy fluoropolymer coating composition and/or an aliphatic polyurea coating composition.

In another aspect, Aspect 5, the present disclosure provides a method of making a photovoltaic module as provided in any of Aspects 1-4, further comprising depositing a transparent conducting oxide layer onto the front transparency to form the front contact; depositing a first semiconductor layer onto the front contact; depositing a second semiconductor layer onto the first semiconductor layer; and depositing a metallic layer onto the second semiconductor layer to form the back contact.

In another aspect, Aspect 6, the present disclosure provides a method of making a photovoltaic module as provided in any of Aspects 1-5, wherein the first semiconductor layer comprises an n-type window layer, and the second semiconductor layer comprises a p-type absorber layer.

In another aspect, Aspect 7, the present disclosure provides a method of making a photovoltaic module as provided in any of Aspects 1-6, wherein the first semiconductor layer comprises an n-type window layer, and the second semiconductor layer comprises a p-type absorber layer, and wherein the window layer comprises cadmium sulfide and the absorber layer comprises cadmium telluride or copper indium gallium selenide.

In another aspect, Aspect 8, the present disclosure provides a method of making a photovoltaic module as provided in any of Aspects 1-7, further comprising depositing an encapsulant material onto the front transparency; and positioning a plurality of electrically interconnected photovoltaic cells onto the encapsulant layer, the photovoltaic cells each comprising a front contact and a back contact on opposite sides of a semiconductor wafer, wherein the photovoltaic cells are positioned with the front contact facing the encapsulant material.

In another aspect, Aspect 9, the present disclosure provides a method of making a photovoltaic module as provided in any of Aspects 1-8, wherein the encapsulant material comprises a clear fluid encapsulant, and further comprising curing the clear fluid encapsulant after positioning the photovoltaic cells and before electrocoating the module.

In another aspect, Aspect 10, the present disclosure provides a method of making a photovoltaic module as provided in any of Aspects 1-9, wherein the encapsulant material comprises ethylene vinyl acetate, and further comprising laminating the encapsulant and the photovoltaic cells before electrocoating the module.

In another aspect, Aspect 11, the present disclosure provides a method of making a photovoltaic module as provided in any of Aspects 1-10, wherein the semiconductor wafer comprises a crystalline silicon wafer, the front contact comprises a transparent conducting oxide layer or a patterned metallic layer deposited onto one side of the crystalline silicon wafer, and the back contact comprises a metallic layer deposited onto an opposite side of the crystalline silicon wafer.

In another aspect, Aspect 12, the present disclosure provides a photovoltaic module comprising a front transparency, a front contact, a semiconductor, a back contact comprising a metallic conducting material, an electrocoat deposited on at least the back contact, and, a back coat deposited onto a back side of the electrocoated module opposite the front transparency.

In another aspect, Aspect 13, the present disclosure provides a photovoltaic module as provided in Aspect 12, wherein the electrocoat comprises a cured cationic epoxy coating composition.

In another aspect, Aspect 14, the present disclosure provides a photovoltaic module as provided in either of Aspects 12 or 13, wherein the back coat comprises a cured polyamide epoxy fluoropolymer coating composition and/or an aliphatic polyurea coating composition.

In another aspect, Aspect 15, the present disclosure provides a photovoltaic module as provided in any of Aspects 12-14, wherein the photovoltaic module comprises a thin-film photovoltaic module, and: the front contact comprises a transparent conducting oxide layer deposited onto the front transparency; the semiconductor comprises an n-type window layer deposited onto the front contact, and a p-type absorber layer deposited onto the window layer; and the back contact comprises a metallic layer deposited onto the absorber layer.

In another aspect, Aspect 16, the present disclosure provides a photovoltaic module as provided in any of Aspects 12-15, wherein the photovoltaic module comprises a thin-film photovoltaic module, and: the front contact comprises a transparent conducting oxide layer deposited onto the front transparency; the semiconductor comprises an n-type window layer deposited onto the front contact, and a p-type absorber layer deposited onto the window layer; and the back contact comprises a metallic layer deposited onto the absorber layer, and wherein the window layer comprises cadmium sulfide and the absorber layer comprises cadmium telluride or copper indium gallium selenide.

In another aspect, Aspect 17, the present disclosure provides a photovoltaic module as provided in any of Aspects 12-16, wherein the photovoltaic module comprises a bulk photovoltaic module comprising a plurality of electrically interconnected photovoltaic cells adhered to the front transparency with an encapsulant material, the photovoltaic cells each comprising a front contact and a back contact on opposite sides of a semiconductor wafer, wherein the photovoltaic cells are positioned with the front contact facing the encapsulant material.

In another aspect, Aspect 18, the present disclosure provides a photovoltaic module as provided in any of Aspects 12-17, wherein the photovoltaic module comprises a bulk photovoltaic module comprising a plurality of electrically interconnected photovoltaic cells adhered to the front transparency with an encapsulant material, and wherein the encapsulant material comprises a cured clear fluid encapsulant and/or ethylene vinyl acetate.

In another aspect, Aspect 19, the present disclosure provides a photovoltaic module as provided in any of Aspects 12-18, wherein the photovoltaic module comprises a bulk photovoltaic module comprising a plurality of electrically interconnected photovoltaic cells adhered to the front transparency with an encapsulant material, the photovoltaic cells each comprising a front contact and a back contact on opposite sides of a semiconductor wafer, wherein the semiconductor wafer comprises a crystalline silicon wafer, the front contact comprises a transparent conducting oxide layer or a patterned metallic layer deposited onto one side of the crystalline silicon wafer, and the back contact comprises a metallic layer deposited onto an opposite side of the crystalline silicon wafer.

Various aspects described in this specification may address certain disadvantages of the vacuum lamination processes in the production of photovoltaic modules. For example, it will be appreciated that the processes described in this specification can eliminate the lamination of preformed backsheets and back side encapsulant material sheets to photovoltaic cells and front transparencies. In addition, the protective coating systems described in the present disclosure can provide advantages to photovoltaic modules, such as good durability, moisture barrier, and/or abrasion resistance, and the like. Prior encapsulants, such as EVA films, can be replaced with fluid encapsulants. Prior backsheets and back side encapsulant materials can be replaced with protective coating systems comprising deposited coatings that provide comparable or superior encapsulation of the photovoltaic cells and the electrical interconnections. Replacement of traditional encapsulant materials can eliminate the need for vacuum lamination.

Various aspects of the present disclosure have been described and illustrated in this specification to provide an overall understanding of the structure, function, properties, and use of the disclosed modules and processes. It is understood that the various aspects described and illustrated in this specification are non-limiting and non-exhaustive. Thus, the disclosure is not limited by the description of the various non-limiting and non-exhaustive aspects disclosed in this specification. The features and characteristics described in connection with various aspects may be combined with the features and characteristics of other aspects. Such modifications and variations are intended to be included within the scope of this specification. As such, the claims may be amended to recite any features or characteristics expressly or inherently described in, or otherwise expressly or inherently supported by, this specification. Further, Applicants reserve the right to amend the claims to affirmatively disclaim features or characteristics that can be present in the prior art. Therefore, any such amendments comply with written description support requirements. The various aspects disclosed and described in this specification can comprise, consist of, or consist essentially of the features and characteristics as variously described herein.

In this specification, other than where otherwise indicated, all numerical parameters are to be understood as being prefaced and modified in all instances by the term “about”, in which the numerical parameters possess the inherent variability characteristic of the underlying measurement techniques used to determine the numerical value of the parameter. At the very least, and not as an attempt to limit the application of the doctrine of equivalents to the scope of the claims, each numerical parameter described in this specification should at least be construed in light of the number of reported significant digits and by applying ordinary rounding techniques.

Also, any numerical range recited in this specification is intended to include all sub-ranges of the same numerical precision subsumed within the recited range, whether explicitly stated or not. For example, a range of “1.0 to 10.0” is intended to include all sub-ranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited in this specification is intended to include all lower numerical limitations subsumed therein and any minimum numerical limitation recited in this specification is intended to include all higher numerical limitations subsumed therein. Accordingly, Applicants reserve the right to amend this specification, including the claims, to expressly recite any sub-range subsumed within the ranges expressly recited herein. All such ranges are intended to be inherently described in this specification such that amending to expressly recite any such sub-ranges would comply with written description support requirements.

The grammatical articles “one”, “a”, “an”, and “the”, as used in this specification, are intended to include “at least one” or “one or more”, unless otherwise indicated. Thus, the articles are used in this specification to refer to one or more than one (i.e., to “at least one”) of the grammatical objects of the article. By way of example, “a photovoltaic cell” means one or more photovoltaic cells, and thus, possibly, more than one photovoltaic cell is contemplated and may be employed or used in an implementation of the described aspects. Further, the use of a singular noun includes the plural, and the use of a plural noun includes the singular, unless the context of the usage requires otherwise.

It should be understood that in various aspects of the present disclosure described herein certain components and/or coats may be referred to as being “adjacent” to one another. In this regard, it is contemplated that adjacent is used as a relative term and to describe the relative positioning of layers, coats, photovoltaic cells, and the like comprising a photovoltaic module. It is contemplated that one coat or component may be either directly positioned or indirectly positioned beside another adjacent component or coat. In various aspects where one component or coat is indirectly positioned beside another component or coat, it is contemplated that additional intervening layers, coats, photovoltaic cells, and the like may be positioned in between adjacent components. Accordingly, and by way of example, where a first coat is said to be positioned adjacent to a second coat, it is contemplated that the first coat may be, but is not necessarily, directly beside and adhered to the second coat.

Any patent, publication, or other disclosure material identified herein is incorporated by reference into this specification in its entirety unless otherwise indicated, but only to the extent that the incorporated material does not conflict with existing definitions, statements, or other disclosure material expressly set forth in this specification. As such, and to the extent necessary, the express disclosure as set forth in this specification supersedes any conflicting material incorporated by reference herein. Any material, or portion thereof, that is said to be incorporated by reference into this specification, but which conflicts with existing definitions, statements, or other disclosure material set forth herein, is only incorporated to the extent that no conflict arises between that incorporated material and the existing disclosure material. Applicant(s) reserve the right to amend this specification to expressly recite any subject matter, or portion thereof, incorporated by reference herein.

The non-limiting and non-exhaustive examples that follow are intended to further describe various non-limiting and non-exhaustive aspects without restricting the scope of the aspects described in this specification.

### EXAMPLES

### Example 1

Thin-film photovoltaic modules comprising a protective coating system comprising an electrocoat and a back coat were evaluated. The photovoltaic modules comprising the protective coating system were compared to photovoltaic modules lacking any protective coatings on the active photovoltaic thin-film coatings All tested photovoltaic modules were obtained from First Solar (Tempe, Ariz., USA) and comprised active photovoltaic thin-film coatings deposited onto 4-inch by 12-inch rectangular glass front transparencies.

The experimental photovoltaic modules were produced by depositing and curing the electrocoat and back coat onto the glass front transparencies having the deposited active photovoltaic thin-film layers. For each experimental module, one half of the panel was electrocoated with Framecoat® II (a cationic epoxy electrocoating composition available from PPG Industries, Inc., Pittsburgh, Pa., USA). A first module (Module A) was partially electrocoated in an electrocoating bath operating under the following conditions (E-coat A): 85° F., 200 volts, 0.3 amps, two minutes, and 11.85 Coulombs. A second module (Module B) was partially electrocoated in an electrocoating bath operating under the following conditions (E-coat B): 85° F., 250 volts, 0.3 amps, two minutes, and 12.13 Coulombs. The deposited electrocoats (i.e., E-coat A and E-coat B) for Modules A and B were cured by baking at 375° F. (191° C.) for 30 minutes and produced cured electrocoats have approximate dry film thicknesses of 0.5-0.6 mils.

After the electrocoat was cured, a polyurea back coat was sprayed onto the entire back side of the electrocoated Module A opposite the front transparency, thus over-coating both the electrocoated portion and the non-electrocoated portion. The polyurea coating composition is described in U.S. patent application “Photovoltaic Modules and Methods of Making the Same” to Hensel, et al. (Attorney Docket No. 9419A1). The deposited polyurea coating composition was cured in ambient air at room temperature. After the electrocoat was cured, a Coraflon® back coat (polyamide epoxy fluoropolymer available from PPG Industries, Inc., Pittsburgh, Pa., USA) was sprayed onto the entire back side of the electrocoated Module B opposite the front transparency, thus over-coating both the electrocoated portion and the non-electrocoated portion. The deposited Coraflon® coating composition was cured by baking at 140° F. (60° C.) for 30 minutes.

The experimental and control photovoltaic modules were evaluated using three environmental simulation tests: (1) damp heat test (damp heat chamber operating at 86% relative humidity, 85° C., and 1000 hours exposure); (2) salt spray test (1000 hours exposure in a salt spray chamber); and (3) thermal cycling test (100 cycles of −40° C. to +85° C.). The results of the simulation tests are described in Table 1.

TABLE 1

| | | | | 1000 hours | 500 and 1000 hrs | |
|---|---|---|---|---|---|---|
| Module | E-coat | Back coat | 500 hours DH | DH | Salt spray | 100 TC |
| A | E-coat A | Polyurea | Bubbles/ | Same as | Some | Back coat |
| | | | delamination on | at 500 hrs | delamination spot | peeled off; |
| | | | non-e-coated side | | on edge | some with PV |
| | | | on back | | | coat (both |
| | | | | | | sides) |
| B | E-coat B | Polyamide | Good | Good | One delamination | Some peel of |
| | | epoxy | | | spot on edge | of back coat |
| | | fluoropolymer | | | | (more on E- |
| | | | | | | coated side) |
| Control | None | None | Corrosion showed | More | More corrosion | Corrosion of |
| | | | up for PV coating | corrosion | showed up for PV | PV coating |
| | | | | showed up | coating | |
| | | | | for PV | | |
| | | | | coating | | |

### A. Initial Visual Inspection

Each experimental and control photovoltaic module was inspected for visual defects before and after each test. The control and experimental modules were free of defects (i.e., corrosion, bubbles, tears, peeling, cracking, delamination, etc.) before exposure testing.

### B. Damp Heat Test

Durability to high temperature and high humidity exposure was determined by subjecting the test modules to a damp heat test procedure. The test modules were exposed to 85° C. and 85% relative humidity for a period of 1000 hours. Test modules were withdrawn from the damp heat chamber for evaluation at time intervals of 500 hours and 1000 hours to evaluate how module performance was affected over time throughout the duration of the test. The withdrawn modules then returned to the damp heat chamber to continue exposure after the 500 hour evaluation.

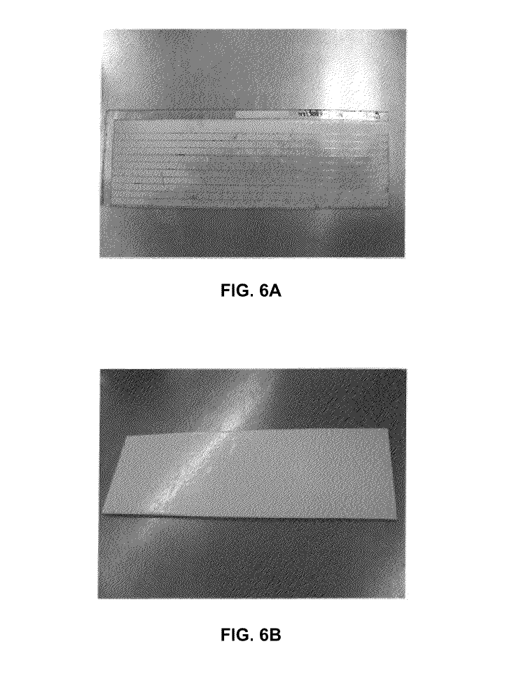

FIGS. 6A and 6B show the control and an experimental module following 1000 hours of damp heat exposure.

FIG. 6A shows the back side of the control photovoltaic module after damp heat testing. As shown in FIG. 6A, visual inspection of the control module (without any protective electrocoat or back coat) showed damage on the right side of the module.

FIG. 6B shows the back side of Module A after 1000 hours of damp heat exposure. Some bubbling and delamination was observed on the back coated/non-electrocoated portion of Module A (shown on the left side of FIG. 6B). In contrast, the electrocoated portion of Module A exhibited no defects following the damp heat exposure (shown on the right side of FIG. 6B). The front sides of the photovoltaic modules of FIGS. 6A and 6B did not exhibit any visual defects following the damp heat exposure. Some minor bubbling and delamination was observed on the back side of the back coated/non-electrocoated portion of Module B (not shown). In contrast, the back side of the electrocoated portion of Module B exhibited no defects following the damp heat exposure.

### C. Salt Spray Test

The durability of the test modules to salt spray was evaluated by subjecting the test modules to a salt spray test procedure. Test modules were subjected to salt spray testing using a 5% salt solution at 95° F. (35° C.) for a period of 1000 hours.

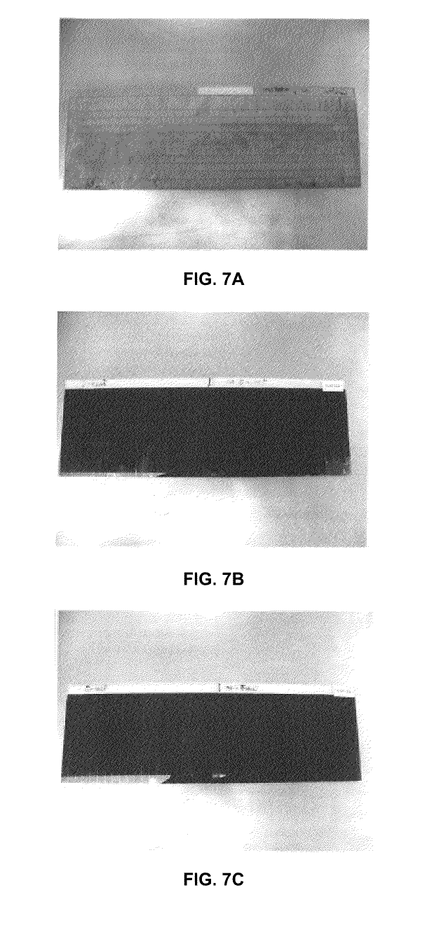

FIGS. 7A-7C show control and experimental modules following salt spray testing. As shown in FIG. 7A, visual inspection of the back side of the control module showed corrosion of the back side of the photovoltaic module.

FIG. 7B shows the front side of Module A following salt spray testing. As shown in FIG. 7B, some delamination was observed on the edge of the module on both the back coated/electrocoated and back coated/non-electrocoated portions.

FIG. 7C shows a single delamination spot on the edge of the front side of Module B on the back coated/electrocoated portion (as shown on the left side of FIG. 7C). Visual inspection of the back sides of Module A and Module B revealed no significant damage post salt spray testing.

### D. Thermal Cycling Test

The durability of the test modules to thermal cycling between −40° C. and 85° C. was evaluated by subjecting the test modules to a thermal cycling test procedure. The thermal cycling was repeated for 100 cycles. Test modules were evaluated after all 100 cycles were completed; no evaluation was performed at intermediate cycling intervals.

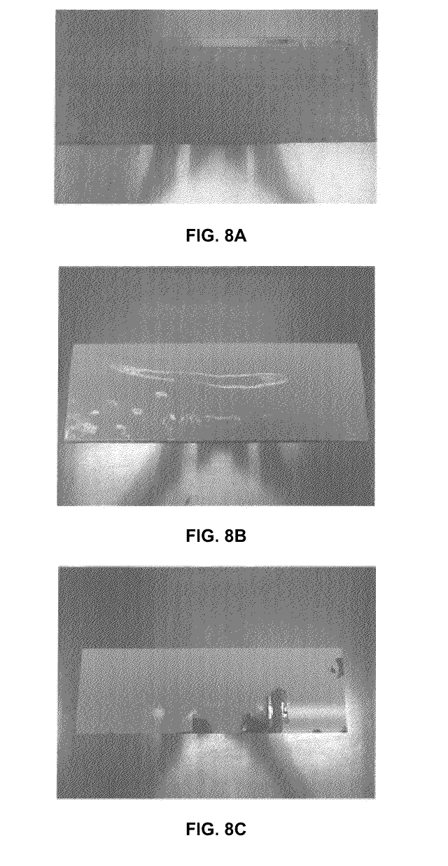

FIGS. 8A-8C show control and experimental modules after thermal cycling. As shown in FIG. 8A, visual inspection of the back side of the control photovoltaic module showed corrosion of the back side of the module.

FIG. 8B shows the back side of Module A following thermal cycling. As shown in FIG. 8B, some delamination was observed on both the back coated/electrocoated and back coated/non-electrocoated portions. Visual inspection of the front side of Module A also showed some delamination spotting (not shown).

FIG. 8C shows delamination spotting on the back side of Module B following thermal cycling. Visual inspection of the front side of Module B also showed some delamination spotting (not shown). Various aspects presented herein may address disadvantages associated with the use of a vacuum lamination processes for the production of photovoltaic modules. For example, various aspects may allow for continuous processing and improved production efficiency with the elimination of a vacuum lamination step(s). In addition, various aspects may allow for the reduction or elimination of vacuum lamination apparatus required to perform the vacuum lamination process, thereby reducing or eliminating capital-intensive equipment that significantly increases production time and costs. Furthermore, the application of vacuum pressure and compression pressure to laminate photovoltaic modules may induce large mechanical stresses on the photovoltaic semiconducting material wafers comprising bulk photovoltaic cells. The semiconducting materials (e.g., crystalline silicon) are generally brittle and the constituent wafers can break under the induced mechanical stresses during the vacuum lamination process. This breakage problem may be exacerbated when attempting to produce photovoltaic modules comprising relatively thin wafers, which more easily break under the mechanical stresses inherent in the vacuum lamination process. Elimination of vacuum lamination may reduce the mechanical stresses involved in the production process. Furthermore, elimination of the lamination of pre-formed backsheets and back side encapsulating material sheets to a photovoltaic cell/front transparency may decrease the mass and volume of the resultant photovoltaic module. In addition, the coating compositions and their related coating systems or configurations of the present disclosure may provide advantages, such as good durability, moisture barrier, and/or abrasion resistance, and the like.

This specification has been written with reference to various aspects. However, it will be recognized by persons having ordinary skill in the art that various substitutions, modifications, or combinations of any of the disclosed aspects (or portions thereof) may be made within the scope of this specification. Thus, it is contemplated and understood that this specification supports additional aspects not expressly set forth herein. Such aspects may be obtained, for example, by combining, modifying, or reorganizing any of the disclosed steps, step sequences, components, elements, features, aspects, characteristics, limitations, and the like, of the various aspects described in this specification. In this manner, Applicant reserves the right to amend the claims during prosecution to add features as variously described in this specification, and such amendments comply with written description support requirements.

What is claimed is:

1. A method for making a photovoltaic module comprising:
electrocoating a module comprising a front transparency, a front contact, a semiconductor, and a back contact, thereby depositing an electrocoat onto the back contact; and
depositing a back coat onto a back side of the electrocoated module opposite the front transparency.

2. The method of claim 1, further comprising:
curing the electrocoat deposited onto the back contact before depositing the back coat onto the back side of the electrocoated module; and
curing the back coat deposited onto the back side of the electrocoated module.

3. The method of claim 1, wherein the electrocoat comprises a cationic epoxy coating composition.

4. The method of claim 1, wherein the back coat comprises a polyamide epoxy fluoropolymer coating composition and/or an aliphatic polyurea coating composition.

5. The method of claim 1, further comprising:
depositing a transparent conducting oxide layer onto the front transparency to form the front contact;
depositing a first semiconductor layer onto the front contact;
depositing a second semiconductor layer onto the first semiconductor layer; and
depositing a metallic layer onto the second semiconductor layer to form the back contact.

6. The method of claim 5, wherein the first semiconductor layer comprises an n-type window layer, and the second semiconductor layer comprises a p-type absorber layer.

7. The method of claim 6, wherein the window layer comprises cadmium sulfide and the absorber layer comprises cadmium telluride or copper indium gallium selenide.

8. The method of claim 1, further comprising:
depositing an encapsulant material onto the front transparency; and
positioning a plurality of electrically interconnected photovoltaic cells onto the encapsulant layer, the photovoltaic cells each comprising a front contact and a back contact on opposite sides of a semiconductor wafer, wherein the photovoltaic cells are positioned with the front contact facing the encapsulant material.

9. The method of claim 8, wherein the encapsulant material comprises a clear fluid encapsulant, and further comprising curing the clear fluid encapsulant after positioning the photovoltaic cells and before electrocoating the module.

10. The method of claim 8, wherein the encapsulant material comprises ethylene vinyl acetate, and further comprising laminating the encapsulant and the photovoltaic cells before electrocoating the module.

11. The method of claim 8, wherein the semiconductor wafer comprises a crystalline silicon wafer, the front contact comprises a transparent conducting oxide layer or a patterned metallic layer deposited onto one side of the crystalline silicon wafer, and the back contact comprises a metallic layer deposited onto an opposite side of the crystalline silicon wafer.

12. A photovoltaic module comprising:
a front transparency;
a front contact;
a semiconductor;
a back contact comprising a metallic conducting material;
an electrocoat deposited on at least the back contact; and
a back coat deposited onto a back side of the electrocoated module opposite the front transparency.

13. The photovoltaic module of claim 12, wherein the electrocoat comprises a cured cationic epoxy coating composition.

14. The photovoltaic module of claim 12, wherein the back coat comprises a cured polyamide epoxy fluoropolymer coating composition and/or an aliphatic polyurea coating composition.

15. The photovoltaic module of claim 12, wherein the photovoltaic module comprises a thin-film photovoltaic module, and:
the front contact comprises a transparent conducting oxide layer deposited onto the front transparency;
the semiconductor comprises an n-type window layer deposited onto the front contact, and a p-type absorber layer deposited onto the window layer; and
the back contact comprises a metallic layer deposited onto the absorber layer.

16. The photovoltaic module of claim 15, wherein the window layer comprises cadmium sulfide and the absorber layer comprises cadmium telluride or copper indium gallium selenide.

17. The photovoltaic module of claim 12, wherein the photovoltaic module comprises a bulk photovoltaic module comprising a plurality of electrically interconnected photovoltaic cells adhered to the front transparency with an encapsulant material, the photovoltaic cells each comprising a front contact and a back contact on opposite sides of a semiconductor wafer, wherein the photovoltaic cells are positioned with the front contact facing the encapsulant material.

18. The photovoltaic module of claim 17, wherein the encapsulant material comprises a cured clear fluid encapsulant and/or ethylene vinyl acetate.

19. The photovoltaic module of claim 17, wherein the semiconductor wafer comprises a crystalline silicon wafer, the front contact comprises a transparent conducting oxide layer or a patterned metallic layer deposited onto one side of the crystalline silicon wafer, and the back contact comprises a metallic layer deposited onto an opposite side of the crystalline silicon wafer.
